(19) United States
(12) Patent Application Publication
(10) Pub. No.: US 2025/0386545 A1
(43) Pub. Date: Dec. 18, 2025

(54) METHOD OF FORMING BACKSIDE VIAS

(71) Applicant: Taiwan Semiconductor Manufacturing Company, Ltd., Hsin-Chu (TW)

(72) Inventors: Yu-Chun Lin, Hsinchu (TW); Po-Yu Huang, Hsinchu (TW); Shih-Chieh Wu, Hsinchu (TW); I-Wen Wu, Hsinchu City (TW); Chen-Ming Lee, Taoyuan County (TW); Mei-Yun Wang, Hsin-Chu (TW); Yuan-Chang Chen, Hsinchu (TW)

(21) Appl. No.: 18/913,520

(22) Filed: Oct. 11, 2024

Related U.S. Application Data
(60) Provisional application No. 63/658,929, filed on Jun. 12, 2024.

(51) Int. Cl. H01L 29/417; H01L 21/285; H01L 29/06; H01L 29/423; H01L 29/66; H01L 29/775; H01L 29/786

(52) U.S. Cl. CPC H10D 30/6729; H01L 21/28518; H10D 30/014; H10D 30/43; H10D 30/6735; H10D 30/6757; H10D 62/121; H10D 64/017; H10D 64/018

(57) ABSTRACT

In an embodiment, an exemplary method includes receiving a structure comprising a fin-shaped active region protruding from a substrate and comprising a channel region and a source/drain region, and a dummy gate stack over the channel region. The method also includes recessing the source/drain region to form a source/drain trench, forming a dielectric layer over the substrate and in the source/drain trench, epitaxially forming a source/drain feature in the source/drain trench and over the dielectric layer, replacing the dummy gate stack with a gate structure, performing an etching process to etch the substrate and the dielectric layer to form an opening exposing a bottom surface of the source/drain feature, forming a dielectric liner extending along surfaces of the dielectric layer and the substrate exposed by the opening, and forming a conductive feature in the opening and under the source/drain feature.

### PRIORITY DATA

This application claims priority to U.S. Provisional Patent Application No. 63/658,929, filed Jun. 12, 2024, which is hereby incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

As integrated circuit (IC) technologies progress towards smaller technology nodes, parasitic capacitance between two adjacent conductive features (e.g., backside vias and gate structures) may have serious bearings on the overall performance of an IC device. While existing methods for forming the backside vias are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor structure, according to one or more aspects of the present disclosure.

FIG. 2 illustrates a fragmentary top view of an exemplary structure to undergo various stages of operations in the method of FIG. 1, according to various aspects of the present disclosure.

FIGS. 3A, 4A, 5A, 6A, 7A, 8A, 9A, 10A, 11A, 12A, 13A, 14A, 15A, 16A, and 17A (FIGS. 3A-17A) illustrate fragmentary cross-sectional views of the structure taken along line A-A′ as shown in FIG. 2 during various fabrication stages in the method of FIG. 1, according to one or more aspects of the present disclosure.

FIGS. 3B, 4B, 5B, 6B, 7B, 8B, 9B, 10B, 11B, 12B, 13B, 14B, 15B, 16B, and 17B (FIGS. 3B-17B) illustrate fragmentary cross-sectional views of the structure taken along line B-B′ as shown in FIG. 2 during various fabrication stages in the method of FIG. 1, according to one or more aspects of the present disclosure.

FIG. 3C illustrates a fragmentary cross-sectional view of the structure taken along line C-C′ as shown in FIG. 2 during various fabrication stages in the method of FIG. 1, according to one or more aspects of the present disclosure.

FIGS. 18A, 19A, 20A illustrate fragmentary cross-sectionals view of a first alternative structure taken along line A-A′ as shown in FIG. 2 during various fabrication stages in the method of FIG. 1, according to one or more aspects of the present disclosure.

FIGS. 18B, 19B, 20B illustrate fragmentary cross-sectional views of the first alternative structure taken along line B-B′ as shown in FIG. 2 during various fabrication stages in the method of FIG. 1, according to one or more aspects of the present disclosure.

FIGS. 21A, 22A illustrate fragmentary cross-sectionals view of a second alternative structure taken along line A-A′ as shown in FIG. 2 during various fabrication stages in the method of FIG. 1, according to one or more aspects of the present disclosure.

FIGS. 21B, 22B illustrate fragmentary cross-sectional views of the second alternative structure taken along line B-B′ as shown in FIG. 2 during various fabrication stages in the method of FIG. 1, according to one or more aspects of the present disclosure.

FIG. 23 depicts an enlarged portion of the second alternative structure, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

As integrated circuit (IC) technologies progress towards smaller technology nodes, multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A gate-all-around (GAA) transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor. Silicide layers and backside vias may be formed under epitaxial layers of source/drain features from its back side. However, the reduced distance between the backside vias and functional gate structures may induce unwanted leakage.

The present disclosure provides a method for enhancing isolation between the functional gate structures and the backside vias. In an exemplary method, after forming a source/drain opening and refilling a lower portion of the source/drain opening with a semiconductor layer, an insulation layer is formed to block a top surface of the semiconductor layer, and an N-type source/drain feature is formed over the insulation layer and in the source/drain opening. After forming the source/drain feature, an etching process is performed to form a backside opening extending through the substrate, semiconductor layer, and insulation layer from back, and a dielectric barrier layer is formed to extend along sidewall surface of the backside opening. A silicide layer and a backside via are then formed under the source/drain feature and in the backside opening. Forming the dielectric barrier layer after forming the backside opening that extends through the insulation layer can enhance isolation between the backside via and adjacent gate structures and reduce leakage current.

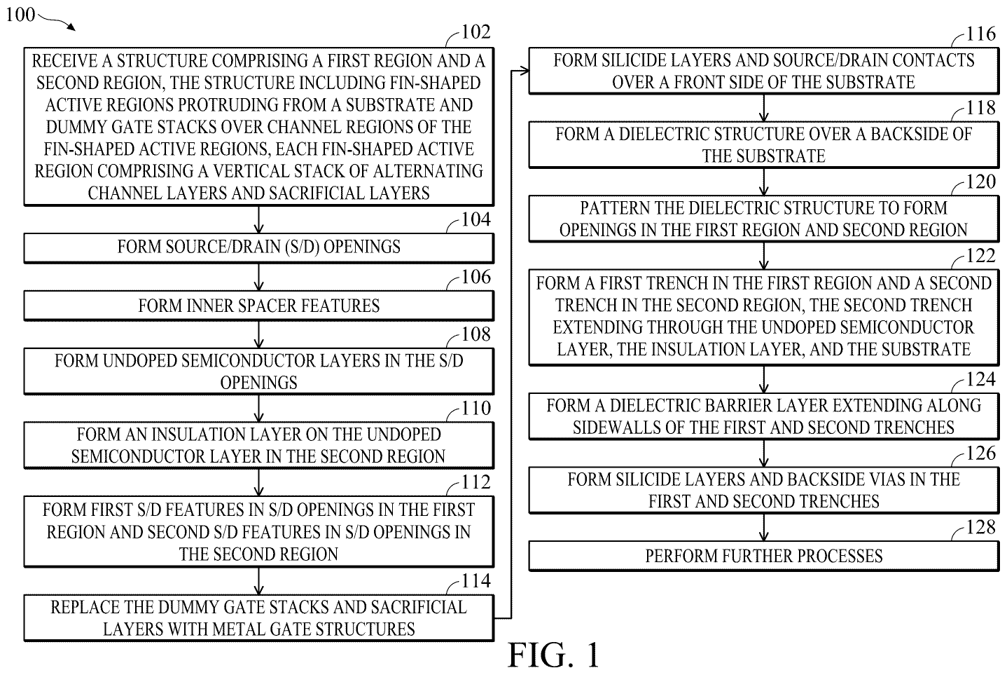

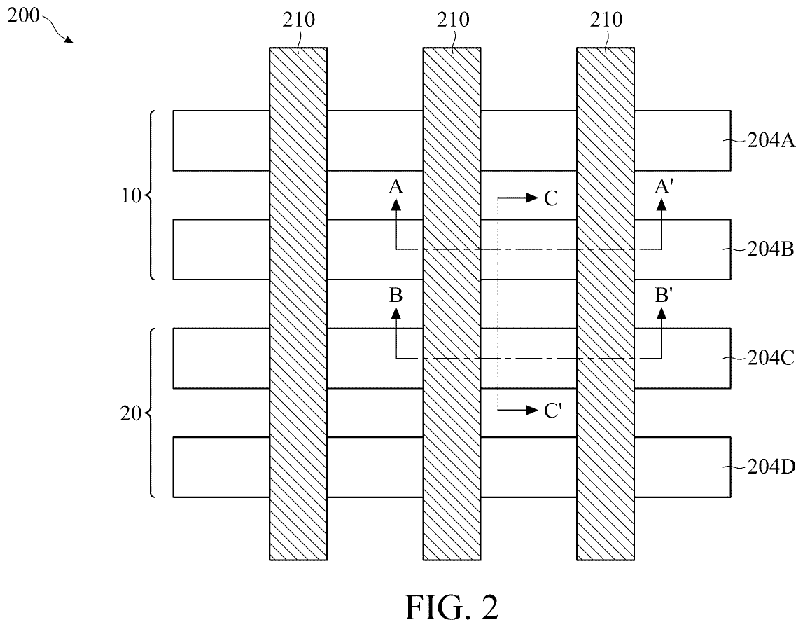

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2-23 which are fragmentary top/cross-sectional views of a structure 200 at different stages of fabrication according to embodiments of method 100. Method 100 is merely an example and is not intended to limit the present disclosure to what is explicitly illustrated therein. Additional steps may be provided before, during and after the method 100, and some steps described can be replaced, eliminated, or moved around for additional embodiments of the method. Not all steps are described herein in detail for reasons of simplicity. Because the structure 200 will be fabricated into a semiconductor structure upon conclusion of the fabrication processes, the structure 200 may be referred to as the semiconductor structure 200 as the context requires. For avoidance of doubts, the X, Y and Z directions in FIGS. 2-23 are perpendicular to one another and are used consistently throughout the present disclosure. Throughout the present disclosure, like reference numerals denote like features unless otherwise excepted.

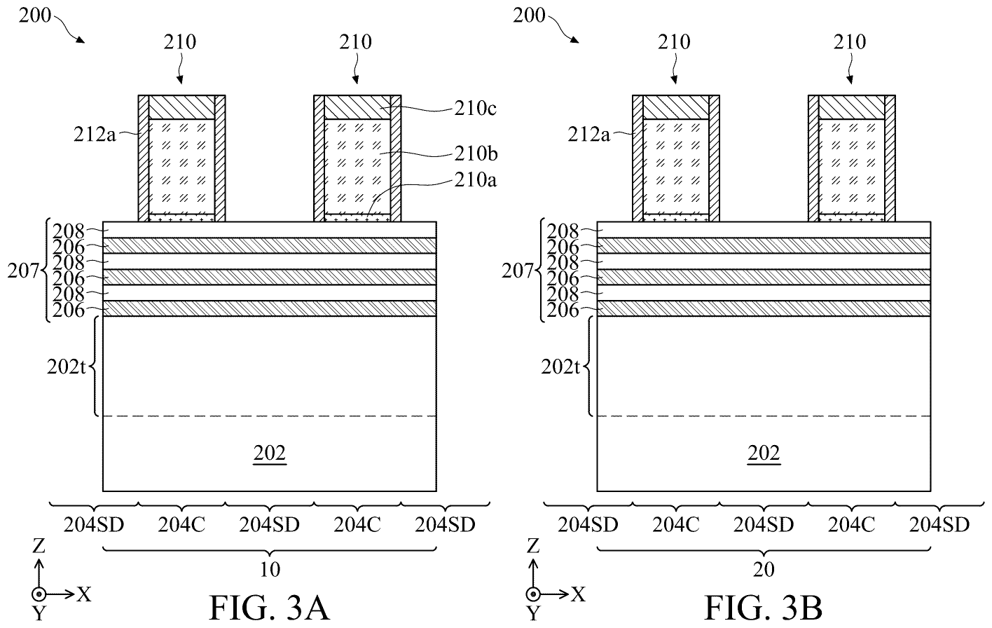

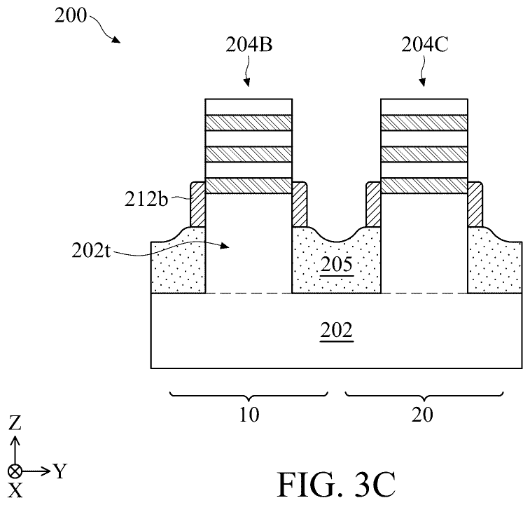

Referring to FIGS. 1, 2, and 3A-3C, method 100 includes a block 102 where a structure 200 that includes a first region 10 and a second region 20 is received. FIG. 2 depicts a fragmentary top view of the structure 200 to undergo various stages of operations in the method of FIG. 1, according to various aspects of the present disclosure. FIG. 3A illustrates a fragmentary cross-sectional view of the structure 200 taken along line A-A′ as shown in FIG. 2, FIG. 3B illustrates a fragmentary cross-sectional view of the structure 200 taken along line B-B′ as shown in FIG. 2, and FIG. 3C illustrates a fragmentary cross-sectional view of the structure 200 taken along line C-C′ as shown in FIG. 2. As illustrated in FIGS. 3A-3C, the structure 200 includes a substrate 202. The substrate 202 may be an elementary (single element) semiconductor, such as silicon (Si) or germanium (Ge) in a crystalline structure; a compound semiconductor, such as silicon carbide (SiC), gallium arsenic (GaAs), gallium phosphide (GaP), indium phosphide (InP), indium arsenide (InAs), and/or indium antimonide (InSb); an alloy semiconductor such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); a non-semiconductor material, such as soda-lime glass, fused silica, fused quartz, and/or calcium fluoride (CaF₂); and/or combinations thereof. In one embodiment, the substrate 202 is a silicon (Si) substrate. The substrate 202 may be uniform in composition or may include various layers, some of which may be selectively etched to form fin-shaped active regions (e.g., the fin-shaped active regions 204A-204D). The layers may have similar or different compositions, and in various embodiments, some substrate layers have non-uniform compositions to induce device strain and thereby tune device performance. Examples of layered substrates include silicon-on-insulator (SOI) substrates 202. In some such examples, a layer of the substrate 202 may include an insulator such as a semiconductor oxide, a semiconductor nitride, a semiconductor oxynitride, a semiconductor carbide, and/or other suitable insulator materials. Doped regions, such as wells, may be formed in the substrate 202. In the embodiments represented by FIG. 2, a portion of the substrate 202 in the first region 10 is doped with an n-type dopant and may be referred to as an n-type well (not shown), and a portion of the substrate 202 in the second region 20 is doped with a p-type dopant and may be referred to as a p-type well (not shown). The n-type dopant may include phosphorus (P) or arsenic (As). The p-type dopant may include boron (B), boron difluoride (BF₂), or indium (In). The n-type well and the p-type well may be formed using ion implantation or thermal diffusion and may be considered portions of the substrate 202. As will be described further below, the first region 10 is p-type field effect transistor (PFET) region for forming PFET(s) and the second region 20 is an n-type field effect transistor (NFET) region for forming NFET(s).

Still referring to FIGS. 2 and 3A-3C, the structure 200 includes a number of fin-shaped active regions (e.g., fin-shaped active regions 204A, 204B, 204C, 204D) protruding from the substrate 202. In the present embodiments, the first region 10 includes the fin-shaped active region 204A and the fin-shaped active region 204B extending vertically from the substrate 202, and the second region 20 includes the fin-shaped active region 204C and the fin-shaped active region 204D extending vertically from the substrate 202. The number of fin-shaped active regions depicted in FIGS. 2 and 3A-3C is just an example, the structure 200 may include any suitable number of active regions. Each of the fin-shaped active regions 204A-204D may be formed from a top portion 202t (shown in FIGS. 3A-3B) of the substrate 202 and a vertical stack 207 of alternating semiconductor layers disposed on a top surface 202ts of the substrate 202. In an embodiment, the vertical stack 207 includes a number of channel layers 208 interleaved by a number of sacrificial layers 206. Each of the channel layers 208 may include a semiconductor material such as, silicon, germanium, silicon carbide, silicon germanium, GeSn, SiGeSn, SiGeCSn, other suitable semiconductor materials, or combinations thereof, while each sacrificial layer 206 has a composition different from that of the channel layers 208. In an embodiment, each of the channel layers 208 includes silicon (Si), the sacrificial layer 206 includes silicon germanium (SiGe). Although the vertical stack 207 of the depicted example includes three channel layers and three sacrificial layers, it is understood that the vertical stack 207 may include any suitable number (e.g., 2 to 10) of channel layers and any suitable number sacrificial layers. The vertical stack 207 and the top portion 202t of the substrate 202 are then patterned to form the fin-shaped active regions 204A-204D. In some embodiments, the patterned top portion 202t of the substrate 202 may be referred to as a mesa structure 202t. Each of the fin-shaped active regions 204 extends lengthwise along the X direction and is divided into channel regions 204C overlapped by dummy gate stacks 210 (to be described below) and source/drain regions 204SD not overlapped by the dummy gate stacks 210. Source/drain region(s) 204SD may refer to a source region or a drain region, individually or collectively dependent upon the context. Each of the channel regions 204C is disposed between two source/drain regions 204SD along the X direction.

The structure 200 also includes isolation features 205 (shown in FIG. 3C) formed around lower portions of the fin-shaped active regions to isolate one fin-shaped active region from an adjacent fin-shaped active region. The isolation features 205 may include shallow trench isolation (STI) features 205. In some embodiments, the isolation features 205 may include silicon oxide, silicon oxynitride, fluorine-doped silicate glass (FSG), a low-k dielectric, combinations thereof, and/or other suitable materials. In embodiments represented in FIG. 3C, upper portions of the fin-shaped active regions 204A-204D rise above the STI features 205 while lower portions of the fin-shaped active regions 204A-204D remain covered or buried in the STI features 205. The isolation feature 205 may be a single-layer structure or a multi-layer structure.

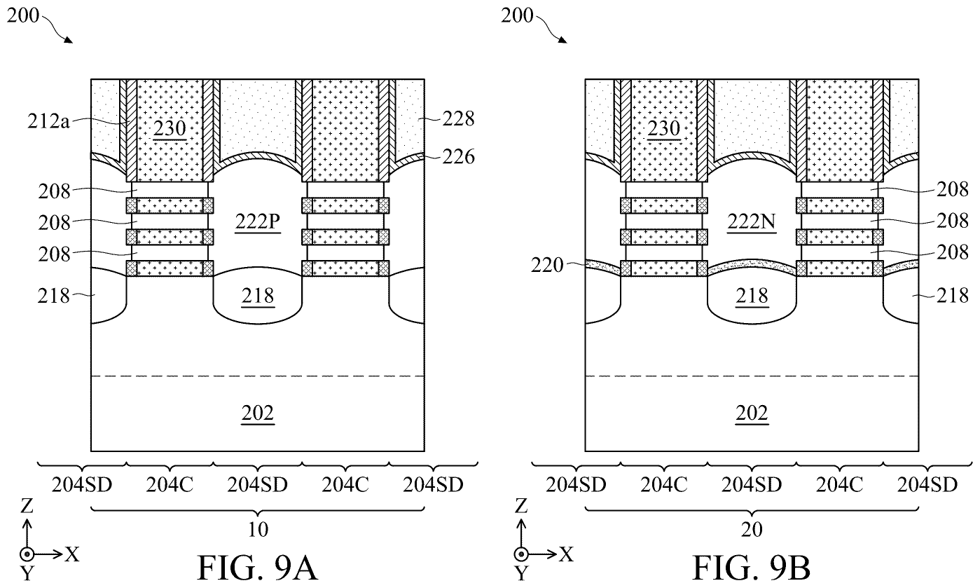

The structure 200 also includes dummy gate stack 210 intersecting with the fin-shaped active regions 204A-204D. Each of the dummy gate stacks 210 includes a dummy gate dielectric layer 210a, a dummy gate electrode layer 210b over the dummy gate dielectric layer 210a, a gate-top hard mask layer 210c over the dummy gate electrode layer 210b. The dummy gate dielectric layer 210a may include silicon oxide. The dummy gate electrode layer 210b may include polysilicon. The gate-top hard mask layer 210c may include silicon oxide layer, silicon nitride, and/or other suitable materials. Suitable deposition process, photolithography and etching process may be employed to form the dummy gate stacks 210. In this embodiment, a gate replacement process (or gate-last process) is adopted where the dummy gate stacks 210 serve as placeholders for functional gate structures (e.g., gate structures 230 shown in FIGS. 9A-9B). Other processes and configurations are possible. Three dummy gate stacks 210 are shown in FIG. 2, but the structure 200 may include any suitable number of dummy gate stacks 210.

The structure 200 also includes gate spacers 212a extending along sidewall surfaces of the dummy gate stacks 210. Each of the gate spacers 212a may be a single-layer structure or a multi-layer structure. In an embodiment, the gate spacer 212a includes a silicon carbonitride (SiCN) layer and a silicon nitride (SiN) on the silicon carbonitride (SiCN) layer. In an example process, a spacer layer (not separately labeled) is conformally deposited over the structure 200, including over the fin-shaped active regions 204A-204D, by atomic layer deposition (ALD), chemical vapor deposition (CVD), or any other suitable deposition process. The term “conformally” may be used herein for ease of description of a layer having substantially uniform thickness over various regions of the structure 200. The spacer layer may include silicon oxide, silicon nitride, silicon oxycarbide, silicon oxycarbonitride, silicon carbonitride, metal nitride, other suitable dielectric materials, or combinations thereof. After the formation of the spacer layer, an etching process is performed to remove portions of the spacer layer over top-facing surfaces of the structure 200 to form the gate spacers 212a extending along sidewalls of the dummy gate stacks 210. The deposition and etching of the spacer layer also forms fin sidewall spacers 212b (shown in FIG. 3C) extending along lower portions of sidewalls of the fin-shaped active regions 204A-204D and disposed on the STI features 205. The gate spacer 212a and fin sidewall spacers 212b have the same composition.

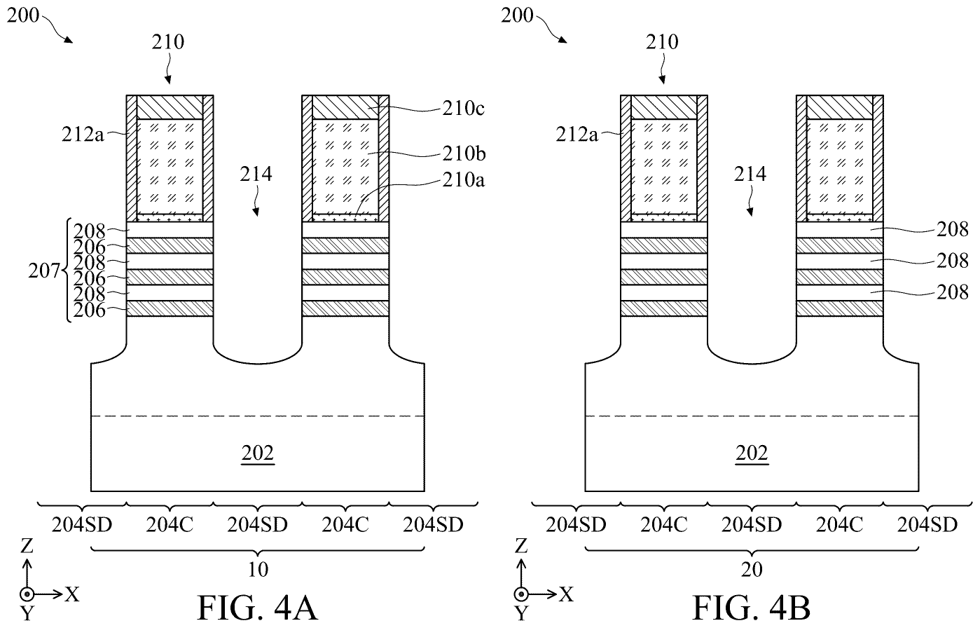

Referring to FIGS. 1 and 4A-4B, method 100 includes a block 104 where source/drain regions 204SD of the fin-shaped active regions 204A-204D are recessed to form source/drain openings 214. In some embodiments, the source/drain regions 204SD of the fin-shaped active regions 204A-204D are anisotropically etched by a plasma etch with a suitable etchant, such as fluorine-containing etchant, oxygen-containing etchant, hydrogen-containing etchant, a fluorine-containing etchant (e.g., CF₄, SF₆, CH₂F₂, CHF₃, and/or C₂F₆), a chlorine-containing etchant (e.g., Cl₂, CHCl₃, CCl₄, and/or BCl₃), a bromine-containing etchant (e.g., HBr and/or CHBr₃), an iodine-containing etchant, other suitable etchants, and/or combinations thereof. In the present embodiments, the source/drain openings 214 extend into the top portion 202t of the substrate 202.

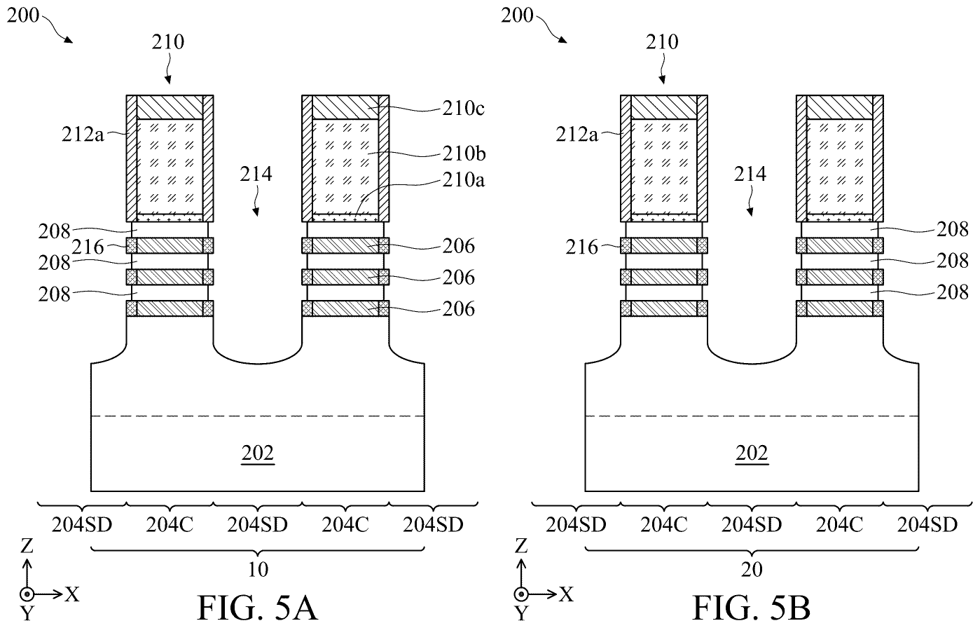

Referring to FIGS. 1 and 5A-5B, method 100 includes a block 106 where inner spacer features 216 are formed. After forming the source/drain openings 214 in the first region 10 and second region 20, the sacrificial layers 206 exposed in the source/drain openings 214 are selectively and partially recessed to form inner spacer recesses (filled by inner spacer features 216). In some embodiments, this selective recess may include a selective isotropic etching process (e.g., a selective dry etching process or a selective wet etching process), and the extent at which the sacrificial layers 206 is recessed is controlled by duration of the etching process. After the formation of the inner spacer recesses, an inner spacer material layer is then conformally deposited using CVD or ALD over the structure 200, including over and into the inner spacer recesses. The inner spacer material layer may include silicon nitride, silicon oxycarbonitride, silicon carbonitride, silicon oxide, silicon oxycarbide, silicon carbide, or silicon oxynitride. The inner spacer material layer is then etched back to form the inner spacer features 216, as illustrated in FIGS. 5A-5B. In some embodiments, a composition of the inner spacer features 216 is different from that of the gate spacers 212a such that the etching back of the inner spacer material layer does not substantially etch the gate spacers 212a.

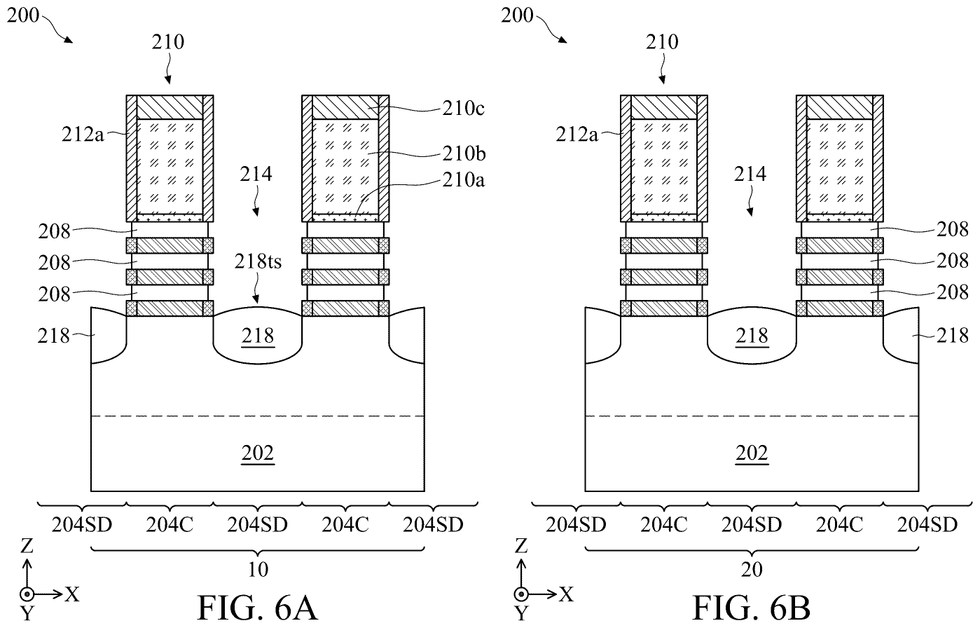

Referring now to FIGS. 1 and 6A-6B, method 100 includes a block 108 where semiconductor layers 218 are formed in the source/drain openings 214. In the present embodiments, after forming the inner spacer features 216, the semiconductor layers 218 are formed in the source/drain openings 214 by using an epitaxial process. Each of the semiconductor layers 218 may be undoped or not intentionally doped. In some embodiments, the semiconductor layers 218 may include undoped silicon (Si), undoped germanium (Ge), undoped silicon germanium (SiGe), or other suitable materials. In an embodiment, the semiconductor layers 218 are formed simultaneously by a common epitaxial process and include undoped silicon (Si). In this depicted example, the top surface 218ts of the semiconductor layer 218 is above the top surface 202ts of the substrate 202 and below the bottom surface of the bottommost layer of the number of channel layers 208 and has a convex profile.

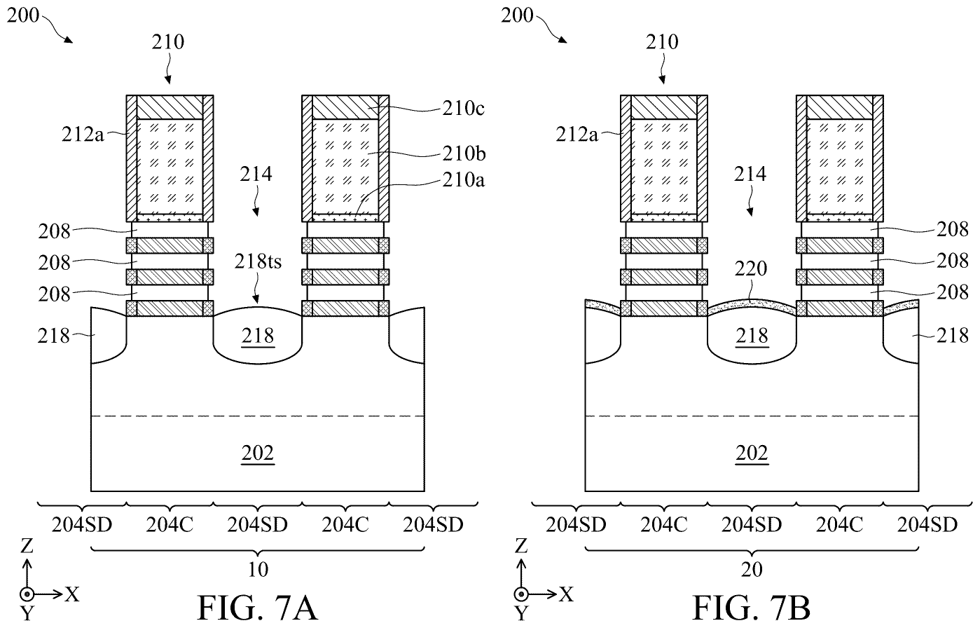

Referring now to FIGS. 1 and 7A-7B, method 100 includes a block 110 where insulation layers 220 are formed in the source/drain openings 214 in the second region 20. In the embodiments, the insulation layer 220 is only formed in the second region 20 for forming N-type transistors and is not formed in the first region 10 for forming P-type transistors. In an example process, a patterned mask (e.g., photoresist layer) is formed to cover the first region 10, and the second region 20 is not covered by the patterned mask. Then, a dielectric material layer (not shown) may be deposited over the substrate 202 by using a chemical vaper deposition (CVD), physical vaper deposition (PVD), atomic layer deposition (ALD) or other suitable processes, and the deposition thickness of the dielectric material layer may be dependent on desired thicknesses of the insulation layer 220 that will be formed in the source/drain opening 214 in the second region 20. In an embodiment, the dielectric material layer is deposited by using a physical vaper deposition (PVD) process. Due to the properties of the PVD process, a portion of the dielectric material layer formed on a top or planar surface are thicker than a portion of the dielectric material layer formed on a side surface. After deposition, an etching process is performed to etch back the dielectric material layer, thereby forming the insulation layer 220 in the source/drain opening 214 in the second region 20. The dielectric material layer may be formed of any suitable dielectric material so long as its composition is different from those of the channel layers 208, the sacrificial layers 206, and the gate-top hard mask layer 210c to allow selective removal by an etching process. In some embodiments, the insulation layer 220 may include silicon oxide, silicon nitride, silicon carbide, or other suitable materials.

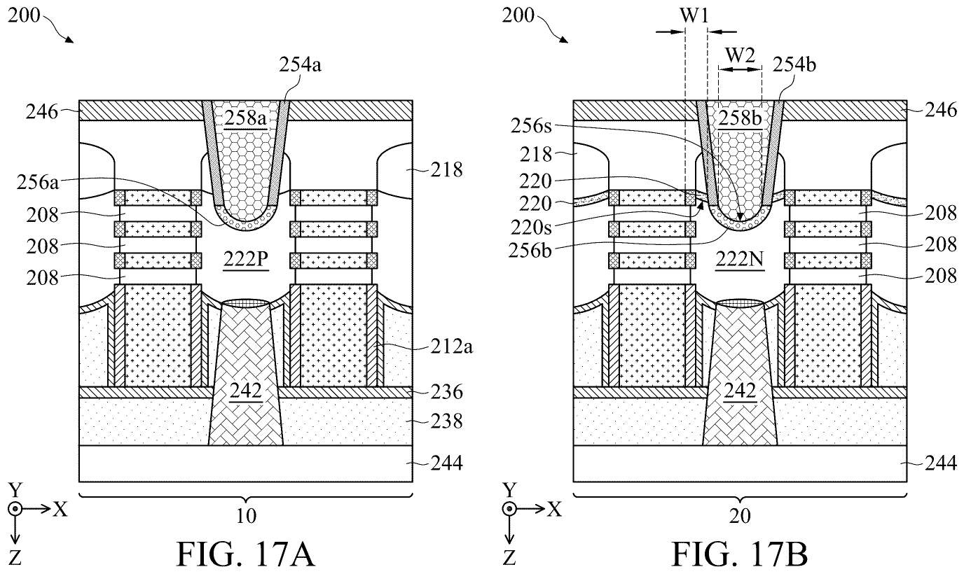

In the present embodiments, the top surface of the insulation layer 220 is below the top surface of the bottommost inner spacer feature 216 of the inner spacer features 216. That is, the insulation layer 220 is not in direct contact with the bottommost layer of the number of channel layers 208. For N-type transistors formed in the second region 20 includes the insulation layer 220, the formation of the insulation layer 220 will substantially suppress and/or eliminate any parasitic transistor formed between the metal gate structures 230, source/drain features 222N, and underlying mesa structure(s) 202t, thereby reducing and/or blocking leakage current through the mesa structure(s) 202t. In addition to this, in the present embodiments, the formation of the insulation layer 220 will provide better isolation between the metal gate structures 230 (shown in FIG. 9B) and the backside via 258b (shown in FIG. 17B) and/or better isolation between the metal gate structure 230 and the backside silicide layer 256b (shown in FIG. 17B).

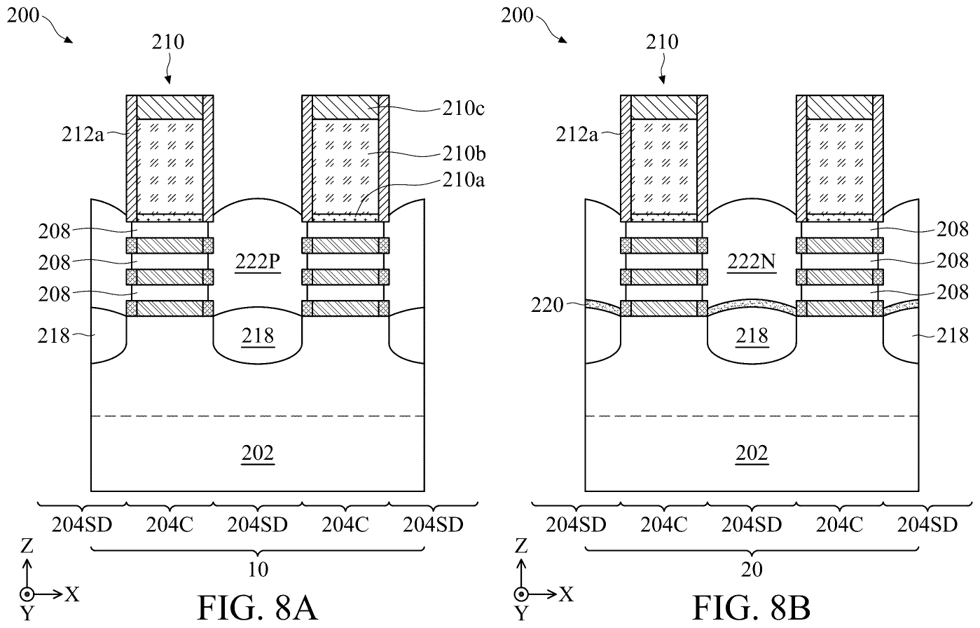

Referring now to FIGS. 1 and 8A-8B, method 100 includes a block 112 where source/drain features 222P and 222N are formed in the source/drain openings 214 in the first region 10 and the second region 20, respectively. Source/drain feature(s) may refer to a source or a drain, individually or collectively dependent upon the context. The source/drain features 222P are coupled to the channel layers 208 of the channel regions 204C in the first region 10. The source/drain features 222N are coupled to the channel layers 208 of the channel regions 204C in the second region 20. The source/drain features 222N and 222P each may be epitaxially and selectively formed from exposed sidewalls of the channel layers 208 by using an epitaxial process, such as vapor phase epitaxy (VPE), ultrahigh vacuum chemical vapor deposition (UHV-CVD), molecular-beam epitaxy (MBE), and/or other suitable processes.

Exemplary n-type source/drain features 222N may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Exemplary p-type source/drain features 222P may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. In some embodiments, each of the n-type source/drain features 222N and the p-type source/drain features 222P may include multiple semiconductor layers with different doping concentrations. The n-type source/drain features 222N and the p-type source/drain features 222P may be formed in any suitable sequential orders.

Referring now to FIGS. 1 and 9A-9B, method 100 includes a block 114 where the dummy gate stacks 210 and the sacrificial layers 206 are replaced by metal gate structures 230. A contact etch stop layer (CESL) 226 and a first interlayer dielectric (ILD) layer 228 are deposited over the structure 200. The CESL 226 may include silicon nitride, silicon oxynitride, and/or other suitable materials and may be formed by ALD, plasma-enhanced chemical vapor deposition (PECVD) process and/or other suitable deposition or oxidation processes. In an embodiment, the CESL 226 has a uniform thickness. The first ILD layer 228 is deposited by a PECVD process or other suitable deposition technique over the structure 200 after the deposition of the CESL 226. The first ILD layer 228 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. A planarization process, such a chemical mechanical polishing (CMP) process may be performed to the structure 200 to remove excess materials and expose top surfaces of the dummy gate electrode layers 210b in the dummy gate stacks 210. A first etching process may be implemented to selectively remove the dummy gate electrode layers 212 and the dummy gate dielectric layers 211 of the dummy gate stacks 210 without substantially removing the gate spacers 212a to form gate trenches in the first region 10 and the second region 20. After the removal of the dummy gate stacks 210, the sacrificial layers 206 in the channel regions 204C are selectively removed to release the channel layers 208 as channel members 208. The selective removal of the sacrificial layers 206 forms gate openings under the gate trenches.

After the removal of the dummy gate stacks 210 and the sacrificial layers 206, metal gate structures 230 are formed in the gate trenches and openings in the first region 10 and the second region 20. The formation of the metal gate structure 230 includes forming an interfacial layer to wrap around and over each of the channel members 208. The interfacial layer may include silicon oxide or other suitable material. The interfacial layer may be formed using a suitable method, such as atomic layer deposition (ALD), chemical vapor deposition (CVD), thermal oxidation, or other suitable method. In an embodiment, the interfacial layer is formed by thermal oxidation and is thus only formed on surfaces of the channel members 208. That is, the interfacial layer does not extend along sidewall surfaces of the gate spacers 212a and does not extend along sidewall surfaces of the inner spacer features 216. In another embodiment, the interfacial layer is formed by ALD and is thus conformally formed on surfaces of the structure 200. That is, the interfacial layer also extends along sidewall surfaces of the gate spacers 212a and sidewall surfaces of the inner spacer features 216. After forming the interfacial layer, a dielectric layer is formed over the structure 200 to wrap around and over each of the channel members 208. In an embodiment, the dielectric layer is deposited conformally over the structure 200. The term “conformally” may be used herein for ease of description of a layer having a substantially uniform thickness over various regions. In some embodiments, the dielectric layer is high-k dielectric layer as its dielectric constant is greater than that of silicon dioxide (˜3.9). In some implementations, the dielectric layer may include titanium oxide (TiO₂), tantalum oxide (Ta₂O₅), hafnium silicon oxide (HfSiO₄), zirconium oxide (ZrO₂), zirconium silicon oxide (ZrSiO₂), aluminum oxide (Al₂O₃), zirconium oxide (ZrO), yttrium oxide (Y₂O₃), SrTiO₃ (STO), BaTiO₃ (BTO), BaZrO, aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The dielectric layer and the interfacial layer may be collectively referred to as a gate dielectric layer.

The formation of the metal gate structure 230 also includes forming a gate electrode over the gate dielectric layer. The gate electrode may be a multi-layer structure that includes at least one work function layer and a metal fill layer. By way of example, the at least one work function layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), or tantalum carbide (TaC). The metal gate structure 230 formed in the first region 10 may include at least a P-type work function layer. The P-type work function layer may include titanium nitride (TiN), tungsten carbonitride (WCN), tantalum nitride (TaN), or molybdenum nitride (MoN). The metal gate structure 230 formed in the second region 20 may include at least an N-type work function layer. The N-type work function layer may include titanium-aluminum based metal, such as titanium aluminum carbon (TiAlC) or titanium aluminum (TiAl). The metal fill layer may include aluminum (Al), tungsten (W), nickel (Ni), titanium (Ti), ruthenium (Ru), cobalt (Co), platinum (Pt), tantalum silicon nitride (TaSiN), copper (Cu), other refractory metals, or other suitable metal materials or a combination thereof. In various embodiments, the gate electrode may be formed by ALD, PVD, CVD, e-beam evaporation, or other suitable process. In various embodiments, a planarization process, such as a chemical mechanical polishing (CMP) process, may be performed to remove excess materials over the first ILD layer 228 to provide a substantially planar top surface and facilitate the performing of further processes.

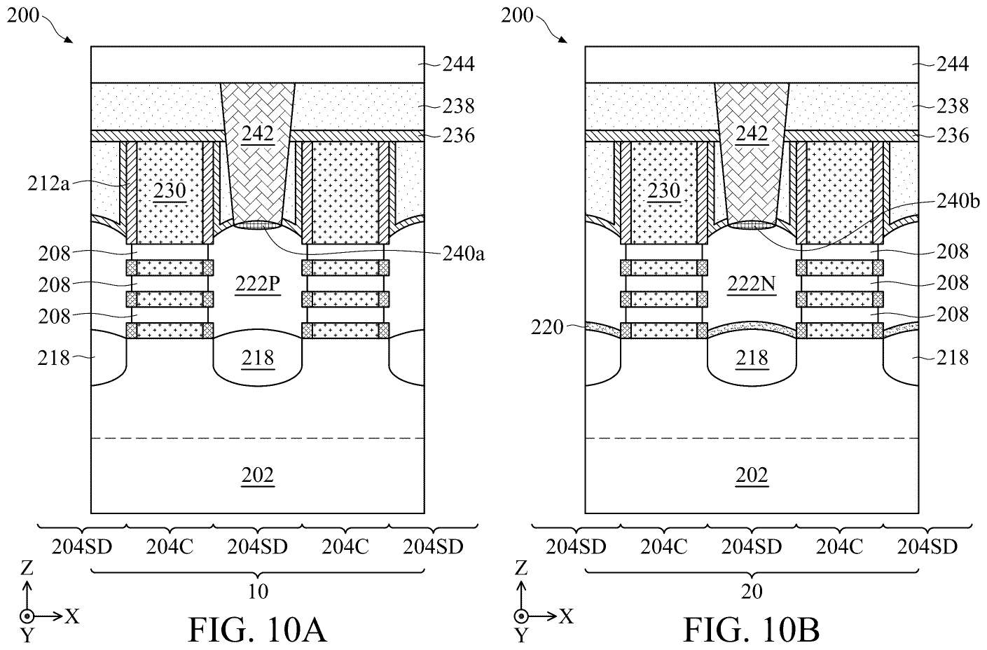

Referring to FIGS. 1 and 10A-10B, method 100 includes a block 116 where silicide layers 240a-240b and source/drain contacts 242 are formed over front side of the substrate 202. In an example process, an etch stop layer 236 and a second ILD layer 238 are deposited over the structure 200. The etch stop layer 236 may be similar to the contact etch stop layer 226 and the second ILD layer 238 may be similar to the first ILD layer 228 in terms of composition and formation processes. The etch stop layer 236 may indicate an etch stop point for forming gate via openings over the metal gate structures 230. Source/drain contact openings (now filled by silicide layers 240a/240b and source/drain contacts 242) are formed to expose the p-type source/drain features 222P or the n-type source/drain feature 222N using a combination of photolithography processes and etch processes. In an example process, a hard mask layer and a photoresist are deposited over the structure 200. The photoresist layer is then exposed to a patterned radiation transmitting through or reflected from a photo mask, baked in a post-exposure bake process, developed in a developer solution, and then rinsed, thereby forming a patterned photoresist layer. The patterned photoresist layer is then applied as an etch mask to etch the hard mask layer to form a patterned hard mask layer. The patterned hard mask layer is then applied as an etch mask to etch the second ILD layer 238, the etch stop layer 236, the first ILD layer 228, and the CESL 226. The etch process for etching the second ILD layer 238, the first ILD layer 228, and the CESL 226 may be a dry etch process that includes use of argon (Ar), a fluorine-containing etchant (for example, SF₆, NF₃, CH₂F₂, CHF₃, C₄F₈, and/or C₂F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, or combinations thereof.

After forming the source/drain contact openings, silicide layers 240a-240b and source/drain contacts 242 are formed therein. To form the silicide layers 240a-240b, a metal precursor (e.g., titanium, tantalum, nickel, cobalt, or tungsten) is deposited over the structure, including on the exposed surface of the n-type source/drain feature 222N and the exposed surface of the p-type source/drain feature 222P. An anneal process is then performed to bring about silicidation in the second region 20 and germinidation in the first region 10 between the metal precursor and the exposed semiconductor surfaces. In some embodiments, the unreacted metal precursor is selectively removed after the formation of the silicide layers 240a-240b. For embodiments in which the metal precursor includes nickel, nickel may react with silicon germanium in the p-type source/drain feature 222P to form the silicide layer 240a and may react with silicon in the n-type source/drain feature 222N to form the silicide layer 240b. Accordingly, the silicide layers 240b may include nickel silicide, and the silicide layer 240a includes nickel silicide, nickel germanide, and nickel germanosilicide.

A conductive layer is then deposited over the structure 200, including in the source/drain contact openings and on the silicide layers 240a/240b. The conductive layer may include aluminum (Al), copper (Cu), tungsten (W), cobalt (Co), ruthenium (Ru), or molybdenum (Mo) or other suitable materials and may be formed by any suitable deposition processes (e.g., CVD). A planarization process, such as a chemical mechanical polish (CMP) process, may be then performed to remove excess portions of the conductive layer to form the source/drain contacts 242. After the performing of the planarization process, top surfaces of the source/drain contacts 242 are coplanar with the second ILD layer 238. Although not shown, in some embodiments, dielectric barrier layers may be formed to extend along sidewall surfaces of the source/drain contacts 242.

After forming the silicide layers 240a and 240b and source/drain contacts 242, other features such as gate vias and an interconnect structure 244 may be formed over the structure 200. In some embodiments, the interconnect structure 244 may include multiple intermetal dielectric (IMD) layers and multiple metal lines or contact vias in each of the IMD layers. In some instances, the IMD layers and the first ILD layer 228 may share similar composition. The metal lines and contact vias in each IMD layer may be formed of metal, such as aluminum, tungsten, ruthenium, or copper. In some embodiments, the metal lines and contact vias may be lined by a barrier layer to insulate the metal lines and contact vias from the IMD layers and to prevent electro-migration. Because the interconnect structure 244 is formed over the front side of the structure 200, the interconnect structure 244 may also be referred to as a frontside interconnect structure 244.

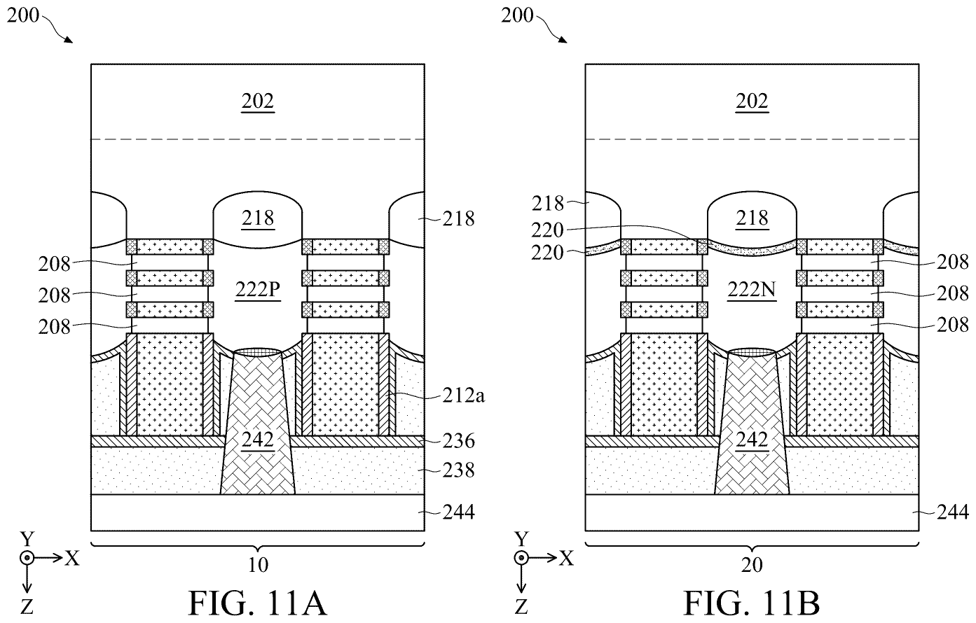

Referring to FIGS. 1 and 11A-11B, 12A-12B, method 100 includes a block 118 where a dielectric structure 245 is formed over a backside of the substrate 202. In an embodiment, with reference to FIGS. 11A-11B, a carrier substrate (not shown) is bonded to the interconnect structure 244. In some embodiments, the carrier substrate may be bonded to the structure 200 by fusion bonding, by use of an adhesion layer, or a combination thereof. In some instances, the carrier substrate may include semiconductor materials (such as silicon), sapphire, glass, polymeric materials, or other suitable materials. In embodiments where fusion bonding is used, the carrier substrate includes a bottom oxide layer and the interconnect structure 244 includes a top oxide layer. After both the bottom oxide layer and top oxide layer are treated, they are placed in plush contact with one another for direct bonding at room temperature or at an elevated temperature. Once the carrier substrate is bonded to the interconnect structure 244 of the structure 200, the structure 200 is flipped over. The back side of the structure 200 is then planarized to reduce a thickness of the substrate 202 from its back. For ease of description, the positional relationships hereafter will be described based on the structure 200 after the flipping, as depicted in the figures.

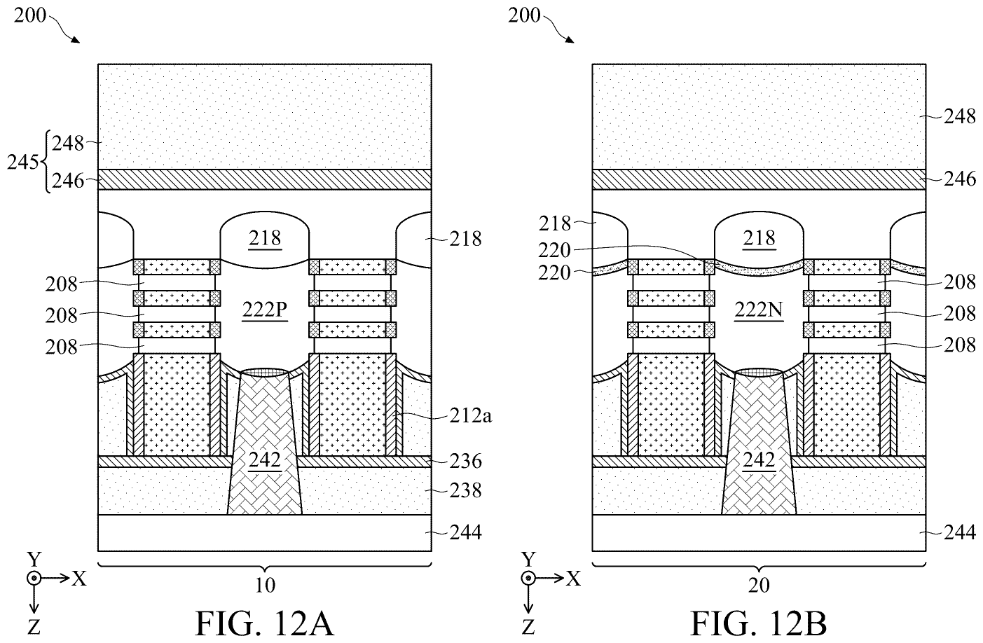

In the present embodiment, with reference to FIGS. 12A-12B, after planarizing the substrate 202, a dielectric structure 245 is formed over the backside of the structure 200. To provide an end point for a subsequent planarization process, the dielectric structure 245 includes a first layer 246 and a second layer 248 having a material composition different from that of the first layer 246. In an embodiment, the first layer 246 includes a nitride layer (e.g., silicon nitride), and the second layer 248 includes an oxide layer (e.g., silicon oxide).

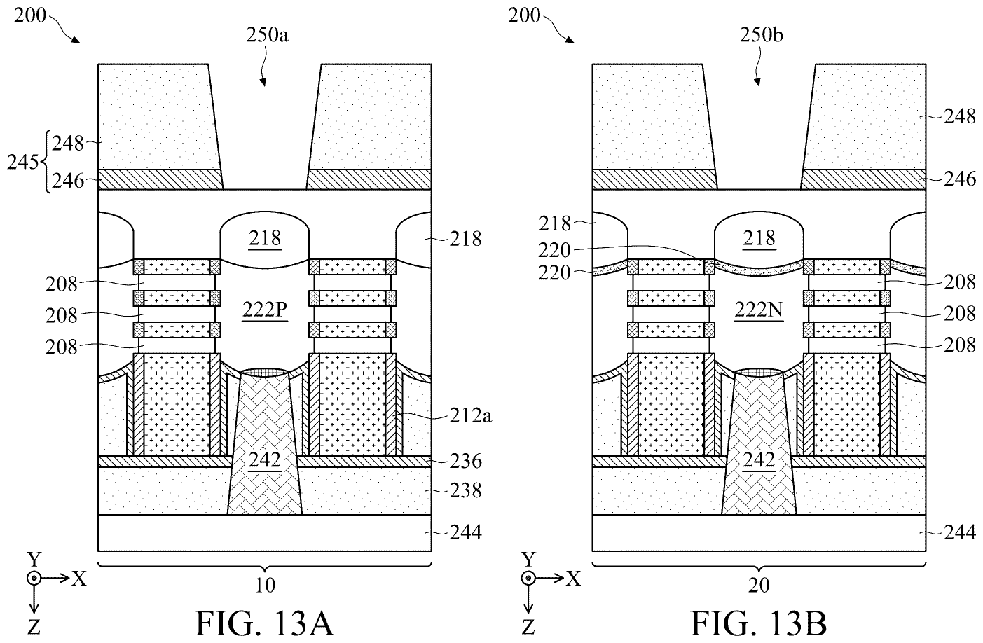

Referring to FIGS. 1 and 13A-13B, method 100 includes a block 120 where the dielectric structure 245 is patterned to form openings 250a in the first region 10 and openings 250b in the second region 20. In an example process, a photoresist is deposited over the backside of the dielectric structure 245. The photoresist layer is then exposed to a patterned radiation transmitting through or reflected from a photo mask, baked in a post-exposure bake process, developed in a developer solution, and then rinsed, thereby forming a patterned photoresist layer. The patterned photoresist layer is then applied as an etch mask to etch the dielectric structure 245 to form a patterned dielectric structure 245. In the present embodiments, the opening 250a is disposed directly over at least a part of the source/drain feature 222P, the opening 250b is disposed directly over at least a part of the source/drain feature 222N.

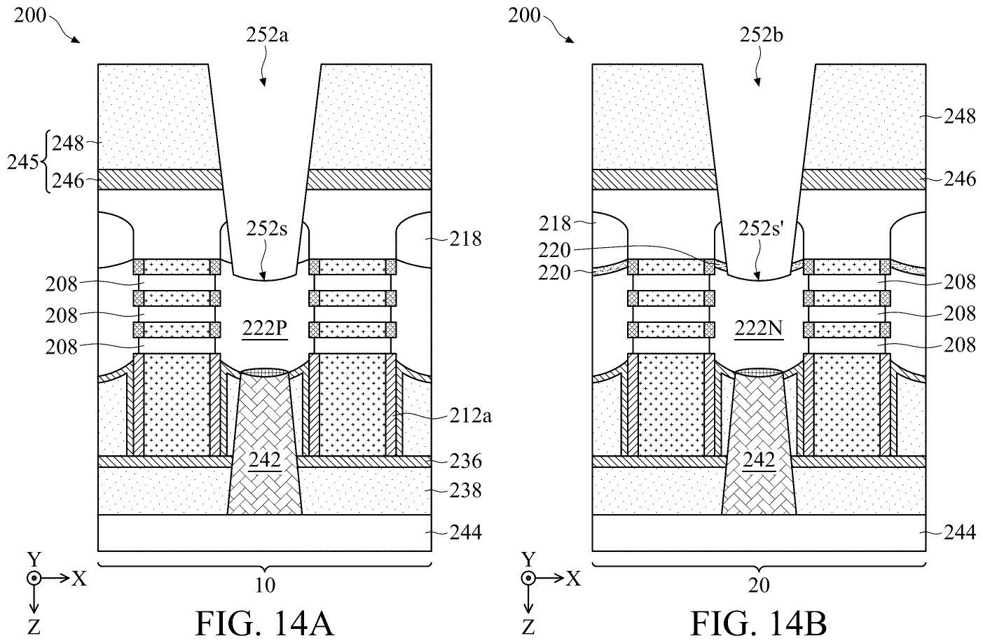

Referring to FIGS. 1 and 14A-14B, method 100 includes a block 122 a first trench 252a is formed in the first region 10 to expose a bottom surface of the source/drain feature 222P and a second trench 252b is formed in the second region 20 to expose a bottom surface of the source/drain feature 222N. While using the patterned dielectric structure 245 as an etch mask, an etching process is performed to etch portions of the substrate 202 and the semiconductor layer 218 disposed directly over the bottom surface of the source/drain feature 222P to vertically extend the opening 250a, thereby forming the first trench 252a in the first region 10. The etching process also etches portions of the substrate 202, the semiconductor layer 218, and the insulation layer 220 disposed directly over the bottom surface of the source/drain feature 222N to vertically extend the opening 250b, thereby forming the second trench 252b in the second region 20.

In some embodiments, the etching process may etch dielectric features (e.g., the insulation layer 220) and semiconductor features (e.g., the substrate 202) at similar etch rates. As illustrated by FIGS. 14A-14B, upon completion of the etching process, the first trench 252a exposes the bottom surface of the source/drain feature 222P and extends through the semiconductor layer 218; the second trench 252b exposes the bottom surface of the source/drain feature 222N and extends through both the semiconductor layer 218 and the insulation layer 220. In some embodiments, the etching process is stopped once the insulation layer 220 is broken through. The first trench 252a may extend into the source/drain feature 222P, and the second trench 252b may extend into the source/drain feature 222N. In this present embodiments, in the cross-sectional view represented by FIGS. 14A-14B, the first trench 252a exposes a portion of a bottom surface of the source/drain feature 222P, and the second trench 252b exposes a portion of a bottom surface of the source/drain feature 222N. That is, a width of surface 252s of the first trench 252a is less than a width of the bottom surface of the source/drain feature 222P, and a width of surface 252s′ of the second trench 252b is less than a width of the bottom surface of the source/drain feature 222N.

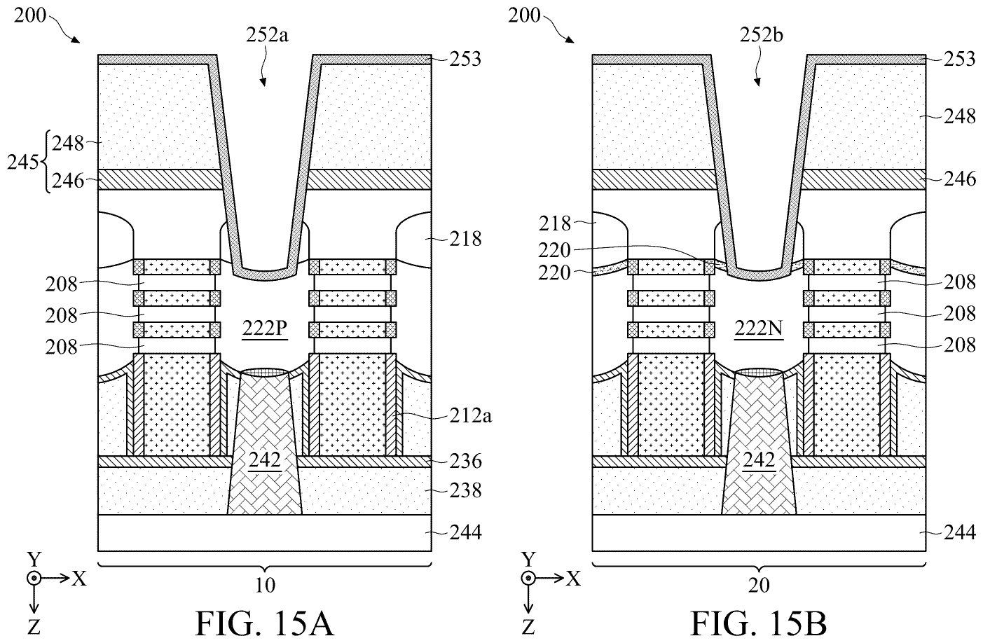

Referring to FIGS. 1 and 15A-15B, 16A-16B, method 100 includes a block 124 where dielectric barrier layers 254 are formed to extend along sidewalls of the first trench 252a and the second trench 252b. With reference to FIGS. 15A-15B, after the formation of the first trench 252a and the second trench 252b, in the present embodiments, to prevent surfaces of the substrate 202 exposed by the trenches 252a-252b from subsequent silicidation process, a dielectric layer 253 is conformally deposited over the backside of the structure 200, including in the first trench 252a and the second trench 252b. In some embodiments, the dielectric layer 253 may include silicon nitride, silicon oxynitride, silicon carbide, or other suitable materials and may be deposited by ALD, CVD, PEALD or other suitable processes.

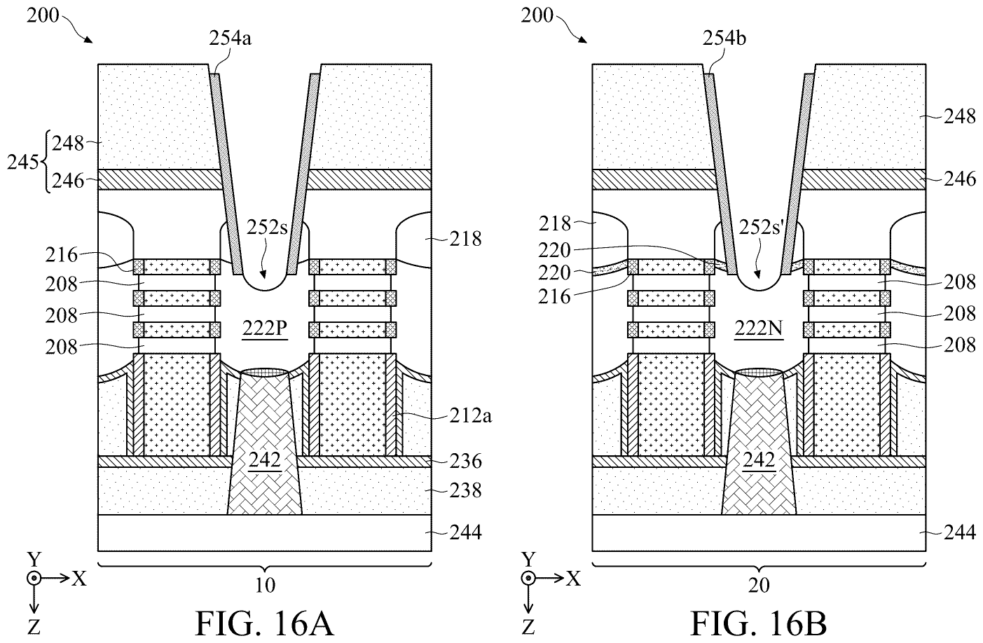

With reference to FIGS. 16A-16B, the dielectric layer 253 is etched back to only keep portions that extend along sidewall surfaces of the trenches 252a-252b, thereby forming the dielectric barrier layer 254a extending along sidewall of the first trench 252a and the dielectric barrier layer 254b extending along sidewall of the second trench 252b. The dielectric barrier layer 254a extends through the semiconductor layer 218 in the first region 10 and is in direct contact with the source/drain feature 222P. The dielectric barrier layer 254b extends through the semiconductor layer 218 and the insulation layer 220 in the second region 20 and in direct contact with the source/drain feature 222N and the insulation layer 220. As depicted by FIG. 16B, the dielectric barrier layer 254b is spaced apart from the bottommost inner spacers 216 by the insulation layer 220. The etch back of the dielectric layer 253 removes portions of the dielectric layer 253 formed on the surfaces 252s and 252s′. In some embodiments, the etch back of the dielectric layer 253 may slightly etch the exposed surfaces of the source/drain feature 222P and the source/drain feature 222N. In an embodiment, the dielectric layer 253 and the insulation layer 220 have the same composition. In another embodiment, a composition of the dielectric layer 253 is different from a composition of the insulation layer 220. Each of the thickness of the dielectric barrier layer 254a and thickness of the dielectric barrier layer 254b is in a range between about 2 nm and about 8 nm. If the thickness is greater than 8 nm, the spacing for forming backside vias may be too small, thereby increasing deposition difficulty and increasing parasitic resistance; if the thickness is less than 2 nm, the thin dielectric barrier layer 254a/254b may not be able to provide satisfactory electrical isolation between the backside via 258a/258b and the substrate 202.

Referring to FIGS. 1 and 17A-17B, method 100 includes a block 126 where silicide layer 256a/256b and backside via 258a/258b are formed in the first trench 252a and the second trench 252b, respectively. After forming the dielectric barrier layer 254a extending along sidewall of the first trench 252a and the dielectric barrier layer 254b extending along sidewall of the second trench 252b, silicide layer 256a/256b and backside via 258a/258b are formed therein. To form the silicide layer 256a/256b, a metal precursor (e.g., titanium, tantalum, nickel, cobalt, or tungsten) is conformally deposited over the backside of the structure 200, including on the exposed portion of bottom surface 252s of the p-type source/drain feature 222P and the exposed portion of the surface 252s′ of the n-type source/drain feature 222N. An anneal process is then performed to bring about silicidation in the second region 20 and germinidation in the first region 10 between the metal precursor and the exposed semiconductor surfaces. In some embodiments, the unreacted metal precursor is selectively removed after the formation of the silicide layers 256a-256b. For embodiments in which the metal precursor includes nickel, nickel may react with silicon germanium in the p-type source/drain feature 222P to form the silicide layer 256a in the first region 10 and may react with silicon in the n-type source/drain feature 222N to form the silicide layer 256b in the second region 20. In an embodiment, the silicide layer 256a is vertically between the dielectric barrier layer 254a and the p-type source/drain feature 222P, the silicide layer 256b is vertically between the dielectric barrier layer 254b and the n-type source/drain feature 222N. Both the silicide layer 256a and the silicide layer 256b may include curved surfaces that curve outward towards the corresponding source/drain feature 222P/222N, respectively. In an embodiment, the silicide layer 256b extends into the source/drain feature 222N and a bottom surface 256s of the silicide layer 256b is above a top surface of the insulation layer 220. In an embodiment, a bottommost surface of the silicide layer 256b is in direct contact with the dielectric barrier layer 254b.

A conductive layer is then deposited over the back side of structure 200, including in the first and second trenches 252a-252b and on the bottom surfaces of the silicide layers 256a-256 b. The conductive layer may include aluminum (Al), copper (Cu), tungsten (W), cobalt (Co), ruthenium (Ru), or molybdenum (Mo) or other suitable materials and may be formed by any suitable deposition processes (e.g., CVD). A planarization process, such as a chemical mechanical polish (CMP) process, may be then performed to remove excess materials over the backside of the patterned first layer 246 to define a final structure of the backside via 258a in the first region 10 and a final structure of the backside via 258b in the second region 20.

As illustrated by FIGS. 17A-17B, in the first region 10, the backside via 258a is spaced apart from the bottommost inner spacer feature 216 by the source/drain feature 222P and the dielectric barrier layer 254a; and in the second region 20, at least a portion of the backside via 258b disposed laterally adjacent to the bottommost inner spacer feature 216 is spaced apart from the bottommost inner spacer feature 216 by a combination of the insulation layer 220 and the dielectric barrier layer 254b. As a result, leakage between the backside via 258b and the metal gate structure 230 disposed adjacent to the inner spacer features 216 may be advantageously reduced or eliminated. The bottommost inner spacer feature 216 and the insulation layer 220 collectively defines a width W1. In an embodiment, the width W1 is in a range between about 3 nm and about 15 nm; If the width W1 is less than 3 nm, the leakage between the backside via 258b and the metal gate structure 230 may disadvantageously affect the device performance; if the width W1 is greater than 15 nm, the backside via 258b may have a small volume and may thus induce high parasitic resistance. In some embodiments, a portion of the backside via 258b that is surrounded by the silicide layer 256b spans a width W2. The width W2 may be in a range between about 5 nm and 15 nm. If the width W2 is greater than 15 nm, then the width W1 may be too small, and the isolation between the backside via 258b and the metal gate structure 230 may be not enough to reduce or even eliminate leakage; if the width W2 is less than 5 nm, the backside via 258b may have a small volume and may induce high parasitic resistance.

Referring to FIG. 1, method 100 includes a block 128 where further processes are performed. Such further processes may include forming a backside interconnect structure over the backside of the structure 200. In some embodiments, the backside interconnect structure may include a multiple intermetal dielectric (IMD) layers and multiple metal lines or contact vias in each of the IMD layers. In some instances, the IMD layers and the first ILD layer 228 may share similar composition. The metal lines and contact vias in each IMD layer may be formed of metal, such as aluminum, tungsten, ruthenium, or copper. In some embodiments, the metal lines and contact vias may be lined by a barrier layer to insulate the metal lines and contact vias from the IMD layers and to prevent electro-migration.

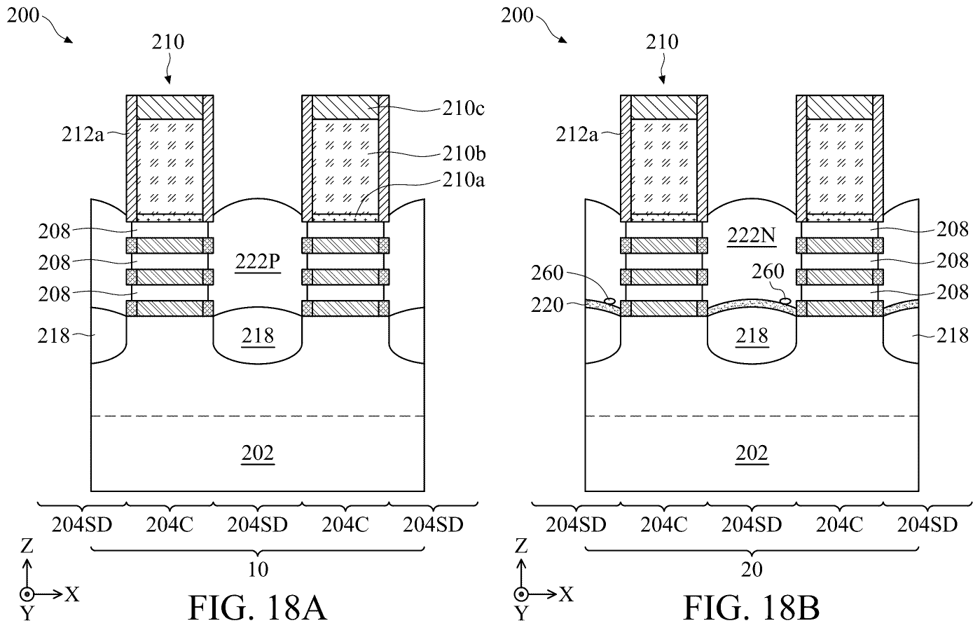

FIGS. 18A-20B depict cross-sectional views of a first alternative structure during various fabrication stages in the method of FIG. 1, according to one or more aspects of the present disclosure. In this alternative embodiment, as depicted by FIGS. 18A-18B, the source/drain feature 222P may be epitaxially grown from the bottom up (i.e., along the Z direction), however, due to the presence of the insulation layer 220, the semiconductor layers 218 in the second region 20 are blocked by the insulation layer 220 and cannot provide exposed semiconductor surfaces for the epitaxial growth of the source/drain features 222N. Instead, the source/drain features 222N are epitaxially formed from exposed sidewalls of the channel layers 208 until semiconductor layers of the source/drain features 222N are merged. The incapability of being epitaxially grown from the bottom up and the incapability of being epitaxially grown along the Y direction lead to formation of void 260 (or air gap 260) enclosed by the source/drain feature 222N and the insulation layer 220, as depicted by FIG. 18B. Put differently, a portion of a top surface of the insulation layer 220 is not in direct contact with a bottom surface of the source/drain feature 222N.

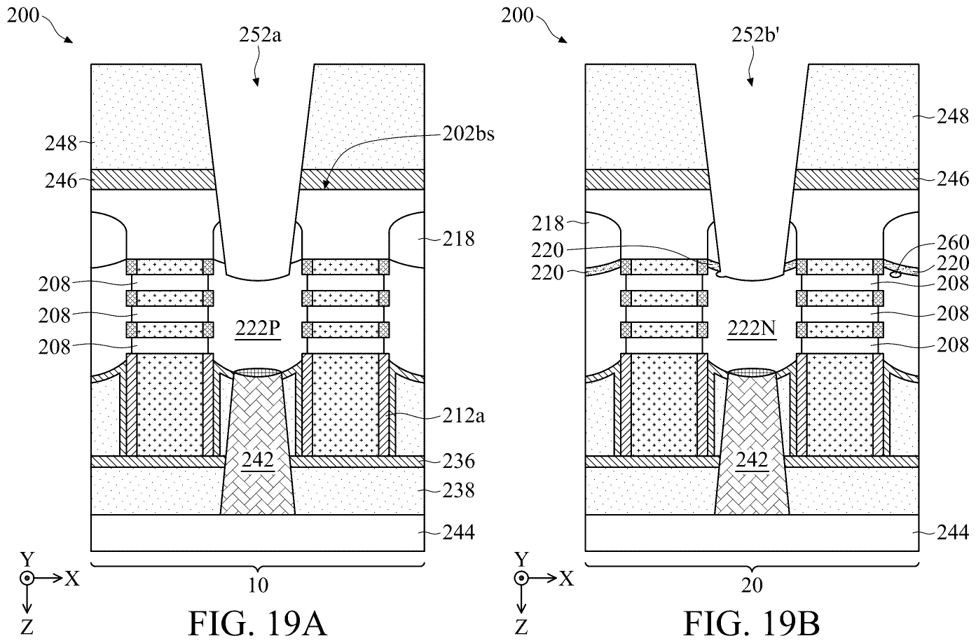

Operation in blocks 114-122 of method 100 are then performed to form first trenches 252a in the first region 10 and second trenches 252b in the second region 20, as represented by FIGS. 19A-19B. Different from the structure 200 depicted in FIG. 14B, in this first alternative embodiment represented by FIG. 19B, since the void 260 was enclosed by a combination of the insulation layer 220 and the source/drain feature 222N, the formation of the second trench 252b etches through the insulation layer 220 and may break this enclosure. As a result, a portion of the second trench 252b may be laterally expanded along the X direction. For example, a portion of the second trench 252b may be vertically disposed between the insulation layer 220 and the source/drain feature 222N and exposes a portion of a top surface of the insulation layer 220. The second trench 252b that is merged with the void 260 may be referred to as the second trench 252b′.

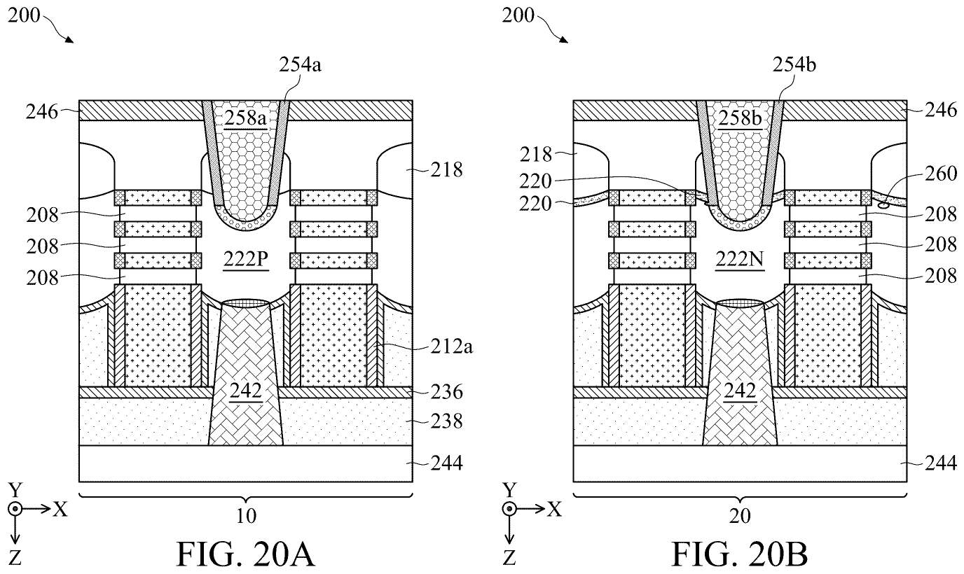

Operation in blocks 124-128 of method 100 are then performed to form the dielectric barrier layers 254a-254b, silicide layers 256a-256b, backside vias 258a-258b to finish the fabrication of the structure 200, as represented by FIGS. 20A-20B. In this embodiment, the dielectric barrier layer 254b may also substantially fill the portion of the second trench 252b′ disposed directly under the insulation layer 220. In this illustrated embodiment represented by FIGS. 20A-20B, the dielectric barrier layer 254a has a symmetrical profile, and the dielectric barrier layer 254b has an asymmetrical profile due to the presence of the void 260 during the formation of the source/drain feature 222N.

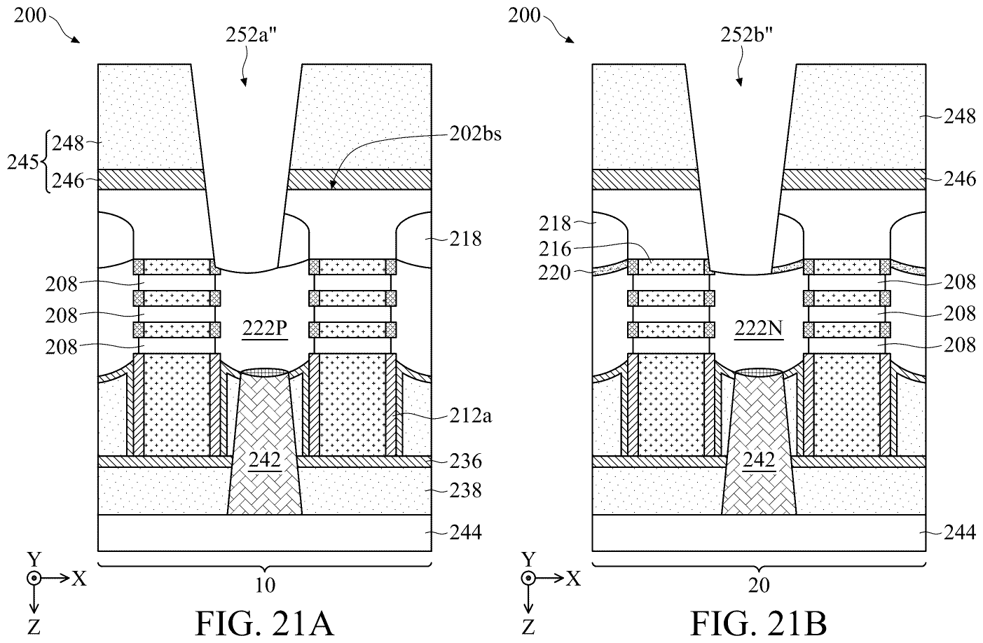

FIGS. 21A-23 depict cross-sectional views of a second alternative structure during various fabrication stages in the method of FIG. 1, according to one or more aspects of the present disclosure. In this alternative embodiment, as represented by FIGS. 21A-21B, misalignment and overlay problems may occur during the patterning of the dielectric structure 245 and thus affect the formation of the first and second trenches 252a-252b. Misalignment and overlay problems during the formation of the first and second trenches 252a-252b may further aggravate the process windows for forming the backside vias 258a-258b, and even degraded integrated chip performance. For example, due to overlay problem, the distance between the backside via 258a/258b and the metal gate structure 230 may be decreased, which may increase leakage or even induce reliability issue. The first trench 252a that undergoes the misalignment and overlay problems is referred to as the first trench 252a″ represented by FIG. 21A, the second trench 252b that undergoes the misalignment and overlay problems is referred to as the second trench 252b″ represented by FIG. 21B. As represented by FIGS. 21A-21B, the first trench 252a″ exposes a portion of the bottommost inner spacer feature 216 in the first region 10, and the second trench 252b″ exposes a portion of the bottommost inner spacer feature 216 in the second region 20. More specifically, portions of the bottommost inner spacer features 216 may be removed during the formation of the first trench 252a″ and the second trench 252b″.

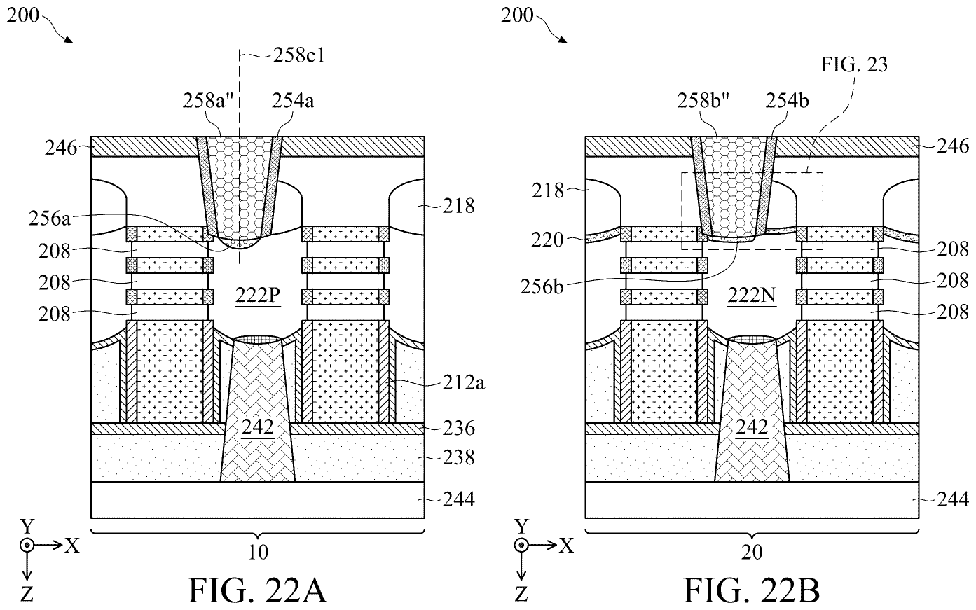

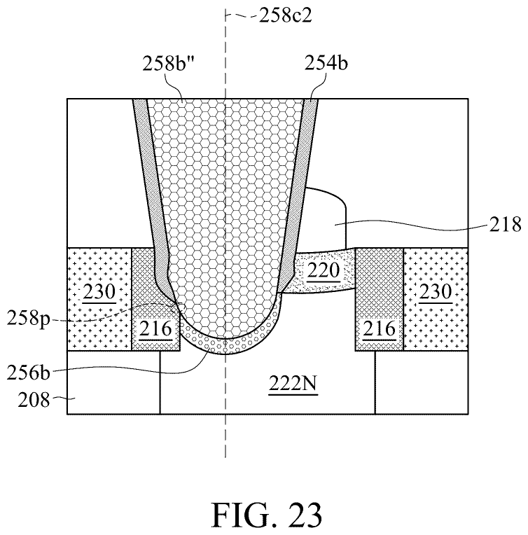

Operation in blocks 124-128 of method 100 are then performed to form the dielectric barrier layers 254a-254b, silicide layers 256a-256b, backside vias 258a″-258b″ to finish the fabrication of the structure 200, as represented by FIGS. 22A-22B. In this embodiment, a center line 258c1 of the backside via 258a″ is offset from a center line of the source/drain feature 222P, and the dielectric barrier layer 254a is in direct contact with one of the bottommost inner spacer features 216. A center line 258c2 (shown in FIG. 23) of the backside via 258a″ is offset from a center line of the source/drain feature 222P, and the dielectric barrier layer 254b is in direct contact with one of the bottommost inner spacer features 216. FIG. 23 depicts an enlarged portion of the structure 200 in the second region 20. As represented by FIG. 23, the silicide layer 256b is disposed between the dielectric barrier layer 254b and the source/drain feature 222N and in direct contact with the one of the bottommost inner spacer features 216. In some embodiments, a portion 258p of the backside via 258b″ is also in direct contact with the one of the bottommost inner spacer features 216 and extends from the dielectric barrier layer 254b and the silicide layer 256b.

Although not intended to be limiting, one or more embodiments of the present disclosure provide many benefits to a semiconductor structure and the formation thereof. For example, isolation between backside via and adjacent gate structures may be enhanced to reduce leakage current.

The present disclosure provides for many different embodiments. Semiconductor structures and methods of fabrication thereof are disclosed herein. In one exemplary aspect, the present disclosure is directed to a method. The method includes receiving a structure comprising a fin-shaped active region protruding from a substrate and comprising a channel region and a source/drain region, and a dummy gate stack over the channel region, recessing the source/drain region to form a source/drain trench, forming a dielectric layer over the substrate and in the source/drain trench, epitaxially forming a source/drain feature in the source/drain trench and over the dielectric layer, replacing the dummy gate stack with a gate structure, performing an etching process to etch the substrate and the dielectric layer to form an opening exposing a bottom surface of the source/drain feature, forming a dielectric liner extending along surfaces of the dielectric layer and the substrate exposed by the opening, and forming a conductive feature in the opening and under the source/drain feature.

In some embodiments, the channel region may include a plurality of channel layers interleaved by a plurality of sacrificial layers, and the method may also include after forming the source/drain trench, selectively recessing the plurality of sacrificial layers to form inner spacer recesses, and forming inner spacer features in the inner spacer recesses. In some embodiments, the method may also include selectively removing the plurality of sacrificial layers, where the gate structure may also wrap around the plurality of channel layers, and a portion of the dielectric liner may be disposed laterally between the conductive feature and the gate structure. In some embodiments, a portion of the dielectric liner may be disposed laterally between the conductive feature and a bottommost inner spacer feature of the inner spacer features. In some embodiments, a top surface of the dielectric liner may be lower than a top surface of the bottommost inner spacer feature. In some embodiments, the forming of the dielectric liner may include, after the performing of the etching process, conformally depositing a dielectric material layer over a backside of the substrate and in the opening, and etching back the dielectric material layer. In some embodiments, the method may also include, before the forming of the dielectric layer, epitaxially forming an undoped semiconductor layer in the source/drain trench, where the opening further extends through the undoped semiconductor layer. In some embodiments, the forming of the conductive feature may include forming a silicide layer in the opening and under the source/drain feature, and forming a conductive layer under the silicide layer to fill a remaining portion of the opening.

In another exemplary aspect, the present disclosure is directed to a method. The method includes forming a source/drain opening extending into a substrate, forming a semiconductor layer in a bottom portion of the source/drain opening, forming a dielectric feature in the source/drain opening and on the semiconductor layer, forming a source/drain feature in the source/drain opening and on the dielectric feature, partially etching the dielectric feature, the semiconductor layer, and a portion of the substrate disposed directly under the semiconductor layer to form a trench, forming a dielectric barrier layer lining sidewall surfaces of the trench, wherein the dielectric barrier layer extends along a portion of the dielectric feature, after the forming of the dielectric barrier layer, forming a silicide layer in the trench, and depositing a conductive layer in the trench and under the silicide layer.

In some embodiments, the method may also include forming a first dielectric layer over a backside of the substrate and a second dielectric layer over a backside of the first dielectric layer, forming a patterned mask over the backside of the substrate, the patterned mask including an opening disposed directly under the source/drain feature, and using the patterned mask as an etch mask to pattern the first dielectric layer and the second dielectric layer.

In some embodiments, a top surface of the dielectric barrier layer may be above a top surface of the dielectric feature. In some embodiments, the source/drain feature may include N-type dopants, the method may also include forming another source/drain opening extending into a substrate, forming another semiconductor layer in a bottom portion of the another source/drain opening, and forming a P-type source/drain feature in the source/drain opening and in direct contact with the another semiconductor layer. In some embodiments, the method may also include forming a stack of alternating channel layers and sacrificial layers, wherein the source/drain opening extends through the stack, after the forming of the source/drain opening, forming inner spacer features disposed between two adjacent layers of the channel layers and between a bottommost layer of the channel layers and the substrate, where a top surface of the dielectric feature may be lower than a top surface of a bottommost inner spacer feature of the inner spacer features. In some embodiments, the conductive layer may be spaced apart from the bottommost inner spacer feature by the dielectric barrier layer. In some embodiments, a portion of the dielectric barrier layer may be disposed directly over the dielectric feature. In some embodiments, in a cross-sectional view cut through the source/drain feature and the inner spacer features, a profile of the dielectric barrier layer may be asymmetrical.

In yet another exemplary aspect, the present disclosure is directed to a semiconductor structure. The semiconductor structure includes a gate structure wrapping around a plurality of nanostructures disposed over a substrate, a source/drain feature coupled to the plurality of nanostructures and adjacent to the gate structure, a dielectric layer disposed between the source/drain feature and the substrate, a backside via disposed under and electrically coupled to the source/drain feature, and a dielectric liner extending through the dielectric layer and the substrate, wherein the backside via is spaced apart from the dielectric layer by the dielectric liner.

In some embodiments, the semiconductor structure may also include a silicide layer disposed between the source/drain feature and the backside via, where a bottom surface of the silicide layer may be above a top surface of the dielectric layer. In some embodiments, the semiconductor structure may also include an inner spacer disposed between the substrate and a bottommost nanostructure of the plurality of nanostructures, where the dielectric layer may be in direct contact with the inner spacer. In some embodiments, the semiconductor structure may also include an undoped semiconductor layer disposed between the dielectric layer and the substrate, where the backside via further extends through the undoped semiconductor layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a structure comprising:
a fin-shaped active region protruding from a substrate and comprising a channel region and a source/drain region, and
a dummy gate stack over the channel region;
recessing the source/drain region to form a source/drain trench;
forming a dielectric layer over the substrate and in the source/drain trench;
epitaxially forming a source/drain feature in the source/drain trench and over the dielectric layer;
replacing the dummy gate stack with a gate structure;
performing an etching process to etch the substrate and the dielectric layer to form an opening exposing a bottom surface of the source/drain feature;
forming a dielectric liner extending along surfaces of the dielectric layer and the substrate exposed by the opening; and
forming a conductive feature in the opening and under the source/drain feature.

2. The method of claim 1, wherein the channel region comprises a plurality of channel layers interleaved by a plurality of sacrificial layers, and the method further comprises:
after forming the source/drain trench, selectively recessing the plurality of sacrificial layers to form inner spacer recesses; and
forming inner spacer features in the inner spacer recesses.

3. The method of claim 2, further comprising:
selectively removing the plurality of sacrificial layers,
wherein the gate structure further wraps around the plurality of channel layers, and a portion of the dielectric liner is disposed laterally between the conductive feature and the gate structure.

4. The method of claim 2, wherein a portion of the dielectric liner is disposed laterally between the conductive feature and a bottommost inner spacer feature of the inner spacer features.

5. The method of claim 4, wherein a top surface of the dielectric liner is lower than a top surface of the bottommost inner spacer feature.

6. The method of claim 1, wherein the forming of the dielectric liner comprises:
after the performing of the etching process, conformally depositing a dielectric material layer over a backside of the substrate and in the opening; and
etching back the dielectric material layer.

7. The method of claim 1, further comprising:
before the forming of the dielectric layer, epitaxially forming an undoped semiconductor layer in the source/drain trench,
wherein the opening further extends through the undoped semiconductor layer.

8. The method of claim 1, wherein the forming of the conductive feature comprises:
forming a silicide layer in the opening and under the source/drain feature; and
forming a conductive layer under the silicide layer to fill a remaining portion of the opening.

9. A method, comprising:
forming a source/drain opening extending into a substrate;
forming a semiconductor layer in a bottom portion of the source/drain opening;
forming a dielectric feature in the source/drain opening and on the semiconductor layer;
forming a source/drain feature in the source/drain opening and on the dielectric feature;
partially etching the dielectric feature, the semiconductor layer, and a portion of the substrate disposed directly under the semiconductor layer to form a trench;
forming a dielectric barrier layer lining sidewall surfaces of the trench, wherein the dielectric barrier layer extends along a portion of the dielectric feature;
after the forming of the dielectric barrier layer, forming a silicide layer in the trench; and
depositing a conductive layer in the trench and under the silicide layer.

10. The method of claim 9, further comprising:
forming a first dielectric layer over a backside of the substrate and a second dielectric layer over a backside of the first dielectric layer;
forming a patterned mask over the backside of the substrate, the patterned mask including an opening disposed directly under the source/drain feature; and
using the patterned mask as an etch mask to pattern the first dielectric layer and the second dielectric layer.

11. The method of claim 10, wherein a top surface of the dielectric barrier layer is above a top surface of the dielectric feature.

12. The method of claim 9, wherein the source/drain feature comprises N-type dopants, the method further comprises:
forming another source/drain opening extending into a substrate;
forming another semiconductor layer in a bottom portion of the another source/drain opening; and
forming a P-type source/drain feature in the source/drain opening and in direct contact with the another semiconductor layer.

13. The method of claim 9, further comprising:
forming a stack of alternating channel layers and sacrificial layers, wherein the source/drain opening extends through the stack;
after the forming of the source/drain opening, forming inner spacer features disposed between two adjacent layers of the channel layers and between a bottommost layer of the channel layers and the substrate,
wherein a top surface of the dielectric feature is lower than a top surface of a bottommost inner spacer feature of the inner spacer features.

14. The method of claim 13, wherein the conductive layer is spaced apart from the bottommost inner spacer feature by the dielectric barrier layer.

15. The method of claim 13, wherein a portion of the dielectric barrier layer is disposed directly over the dielectric feature.

16. The method of claim 15, wherein in a cross-sectional view cut through the source/drain feature and the inner spacer features, a profile of the dielectric barrier layer is asymmetrical.

17. A semiconductor structure, comprising:
a gate structure wrapping around a plurality of nanostructures disposed over a substrate;
a source/drain feature coupled to the plurality of nanostructures and adjacent to the gate structure;
a dielectric layer disposed between the source/drain feature and the substrate;
a backside via disposed under and electrically coupled to the source/drain feature; and
a dielectric liner extending through the dielectric layer and the substrate, wherein the backside via is spaced apart from the dielectric layer by the dielectric liner.

18. The semiconductor structure of claim 17, further comprising:
a silicide layer disposed between the source/drain feature and the backside via, wherein a bottom surface of the silicide layer is above a top surface of the dielectric layer.

19. The semiconductor structure of claim 17, further comprising:
an inner spacer disposed between the substrate and a bottommost nanostructure of the plurality of nanostructures, wherein the dielectric layer is in direct contact with the inner spacer.

20. The semiconductor structure of claim 17, further comprising:
an undoped semiconductor layer disposed between the dielectric layer and the substrate, wherein the backside via further extends through the undoped semiconductor layer.
